(19) United States
(12) Patent Application Publication
(10) Pub. No.: US 2022/0312610 A1
(43) Pub. Date: Sep. 29, 2022

(54) Chassis Including A Slot And Guiding Extensions

(71) Applicant: Quanta Computer Inc., Taoyuan City (TW)

(72) Inventors: Chun CHANG, Taoyuan City (TW); Kai-Yuan CHUANG, Taoyuan City (TW); Wei-Pin CHEN, Taoyuan City (TW); Jyue HOU, Taoyuan City (TW)

(21) Appl. No.: 17/216,063

(22) Filed: Mar. 29, 2021

(51) Int. Cl. H05K 5/02; H05K 7/14

(52) U.S. Cl. CPC H05K 5/0291; H05K 7/1488; H05K 5/0217

(57) ABSTRACT

A chassis includes at least one slot and a plurality of guiding extensions. The at least one slot is configured for receiving a plurality of first storage devices (e.g., E1.S carriers) or a second storage device (e.g., 1×2.5 inch hard drive disk (HDD)). The at least one slot is formed by a top wall, a bottom wall, a first side wall, and a second side wall. The guiding extensions extend into the at least one slot. The guiding extensions include a first set of guiding extensions and a second set of guiding extensions. The first set of guiding extensions configured to receive and secure one of the first storage devices. The second set of guiding extensions configured to receive and secure a second one of the first storage devices.

### FIELD OF THE INVENTION

The present invention relates generally to a chassis including a slot and guiding extensions, and more specifically, a chassis configured to be used in a computer system.

### BACKGROUND OF THE INVENTION

In today's server applications, chassis are formed to receive and contain storage devices. The chassis are typically designed and configured to hold a specific sized and type of storage device. One disadvantage of such chassis designed to hold a specific sized and type of storage device is the lack of flexibility to hold other storage devices.

It would be desirable to have a chassis that has flexibility in its configuration such that the chassis can hold multiple types of storage devices. It would also be desirable to have a chassis that is efficient in installing storage devices. It would be further desirable to have a simple and cost-effective chassis to hold storage devices, without needing additional parts or having to modify the chassis design.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to one aspect of the present disclosure, a chassis includes at least one slot and a plurality of guiding extensions. The at least one slot is configured for receiving a plurality of E1.S carriers or a 1×2.5 inch hard drive disk (HDD). The at least one slot is formed by a top wall, a bottom wall, a second end wall, a first side wall, and a second side wall. The plurality of guiding extensions extends into the at least one slot. The plurality of guiding extensions includes a first set of guiding extensions and a second set of guiding extensions. The first set of guiding extensions is configured to receive and secure one of the plurality of E1.S carriers. The second set of guiding extensions is configured to receive and secure a second one of the plurality of E1.S carriers.

According to a configuration of the above implementation, the at least one slot of the chassis is a plurality of slots.

According to another configuration of the above implementation, the first set of guiding extensions is located at or adjacent to the top wall, and the second set of guiding extensions is located at or adjacent to the bottom wall.

In another implementation, at least one of the plurality of guiding extensions is “L” shaped. In a further implementation, at least one of the plurality of guiding extensions is generally rectangular shaped.

In yet another implementation, the chassis further includes the plurality of E1.S carriers secured in one of the at least one slot. Each of the plurality of E1.S carriers includes a bottom surface, a top surface, a first side, and an opposing second side. The first side forms a first elongated groove extending inwardly therefrom, and the opposing second side forms a second elongated groove extending inwardly therefrom. In one implementation, the first and second elongated grooves are located adjacent to the bottom wall of each of the plurality of E1.S carriers. In a further implementation, the at least one slot of the chassis is a plurality of slots, in which each of the plurality of slots includes two of the plurality of E1.S carriers.

In a further aspect of the above implementation, the chassis further includes the plurality of E1.S carriers secured in one of the at least one slot. Each of the plurality of E1.S carriers includes a first end, an opposing second end, a first side, an opposing second side, a top surface, and a bottom surface. The top or the bottom surface includes a securing protuberance configured to secure one of the plurality of E.1.S carriers with the chassis via the plurality of guiding extensions. The securing protuberance in one embodiment has a cross-sectional shape being in the form of a letter “T”.

According to another aspect of the present disclosure, a chassis includes at least one slot and a plurality of guiding extensions. The at least one slot is configured for receiving a plurality of first storage devices or a second storage device. The at least one slot is formed by a first end wall, a second end wall, a first side wall, and a second side wall. The plurality of guiding extensions extends into the at least one slot. The plurality of guiding extensions includes a first set of guiding extensions and a second set of guiding extensions. The first set of guiding extensions is configured to receive and secure one of the plurality of first storage devices. The second set of guiding extensions is configured to receive and secure a second one of the plurality of first storage devices.

In a further aspect of the above implementation, the at least one slot of the chassis is a plurality of slots.

In a further implementation, the first set of guiding extensions is located at or adjacent to the top wall, and the second set of guiding extensions is located at or adjacent to the bottom wall.

In yet another implementation, at least one of the plurality of guiding extensions is “L” shaped.

In yet another implementation, at least one of the plurality of guiding extensions is generally rectangular shaped.

According to a further aspect of the present disclosure, a computer system comprising a chassis. The chassis includes at least one slot and a plurality of guiding extensions. The at least one slot is configured for receiving a plurality of first storage devices or a second storage device. The at least one slot is formed by a first end wall, a second end wall, a first side wall, and a second side wall. The plurality of guiding extensions extends into the at least one slot. The plurality of guiding extensions includes a first set of guiding extensions and a second set of guiding extensions. The first set of guiding extensions is configured to receive and secure one of the plurality of first storage devices. The second set of guiding extensions is configured to receive and secure a second one of the plurality of first storage devices.

In a further aspect of the above implementation, the plurality of first storage devices is a plurality of E1.S carriers, and the second storage device is a 1×2.5 inch hard drive disk (HDD).

In a further implementation, the computer system is a server.

In yet another implementation, the at least one slot of the chassis is a plurality of slots.

In yet another implementation, the first set of guiding extensions is located at or adjacent to the top wall, and the second set of guiding extensions is located at or adjacent to the bottom wall.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1A is a front view of a storage device (E1.S carrier), in accordance with one embodiment of the present disclosure.

FIG. 1B is an enlarged view of area 1B in FIG. 1A.

FIG. 2 is a generally top perspective view of two storage devices of FIGS. 1A, 1B being inserted into a chassis, in accordance with one embodiment of the present disclosure.

FIG. 3A is an angled front view of a partially-shown chassis of FIG. 2.

FIG. 3B is a front view of the chassis of FIG. 2.

FIG. 4 is a front perspective view of a plurality of storage devices of FIGS. 1A, 1B inserted into a plurality of slots of the partially-shown chassis of FIG. 2.

FIG. 5 is a front perspective view of another storage device (a hard disk drive (HDD) carrier) inserted into the partially-shown chassis of FIG. 2.

FIG. 6 is a side perspective view of yet another storage device (another E1.S carrier), in accordance with another embodiment of the present disclosure.

FIG. 7 is an enlarged cross-sectional view of the storage device of FIG. 6 being engaged with a plurality of guiding extensions of a chassis.

### DETAILED DESCRIPTION

According to one aspect of the present disclosure, a chassis includes at least one slot and a plurality of guiding extensions. The at least one slot is configured for receiving a plurality of first storage devices (e.g., E1.S carriers) or a second storage devices (e.g., a 1×2.5 inch hard drive disk (HDD)). The at least one slot is formed by a first end wall, a second end wall, a first side wall, and a second side wall. The plurality of guiding extensions extends into the at least one slot. The plurality of guiding extensions includes a first set of guiding extensions and a second set of guiding extensions. The first set of guiding extensions is configured to receive and secure one of the first storage devices. The second set of guiding extensions is configured to receive and secure a second one of the first storage devices.

The chassis is configured to be implemented in a computer system. The computer system is in electrical communication with the inserted storage devices. One computer system in which the chassis may be implemented in is a server. In one embodiment, a server includes memory, a processor, a cooling fan, a power supply, heat syncs, and a chassis.

It is contemplated that the chassis may be implemented in other computer systems such as network switches, stand-alone computers, or storage units (e.g., just a bunch of disks (JBOD)).

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

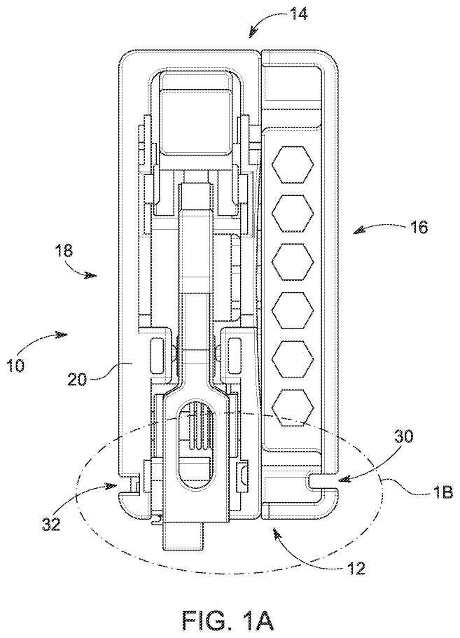

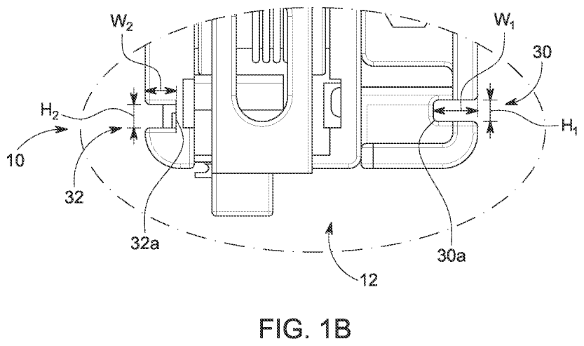

Referring to FIGS. 1A, 1B, a front view of a storage device 10 is shown according to one embodiment. The storage device 10 is an E1.S carrier. An E1.S carrier is a solid state drive (SSD) building block that is designed for high volume hyperscale, system flexibility, modular scaling, increased storage density, improved serviceability, and efficient cooling optimized, for example, for 1U servers or in other applications.

The storage device 10 includes a bottom surface 12, a top surface 14, a first side 16, and an opposing second side 18. The first side 16 forms a first elongated groove 30 extending inwardly therefrom. The opposing second side 18 forms a second elongated groove 32 extending inwardly therefrom. The first and second elongated grooves 30, 32 are located adjacent to the bottom surface 12 of the storage device 10 in FIG. 1A.

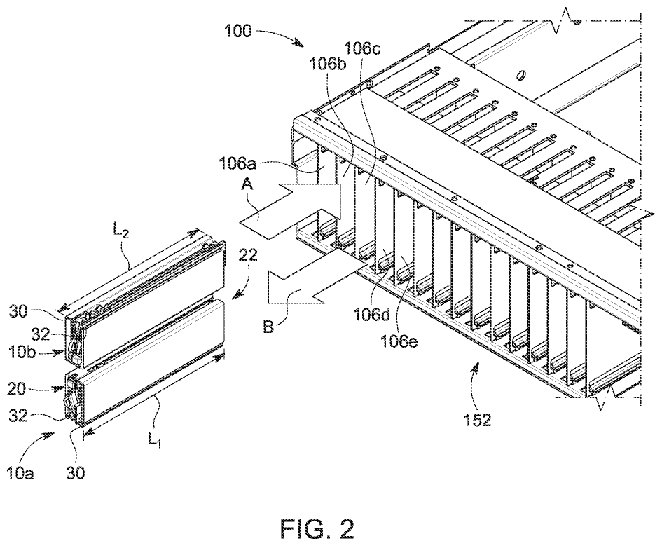

The first and second elongated grooves 30, 32 of the storage device 10, as will be discussed below, are configured to assist in securely engaging or fixing the storage device 10 into a slot of a chassis. The first and second elongated grooves 30, 32 as best shown in FIG. 1B are sized and shaped differently. The first elongated groove 30 has a width W1 and a height H1. The width W1 is generally from about 1 to about 4 mm and, more specifically, from about 1.5 to about 3 mm, or from about 1.5 to about 2.5 mm. The height H1 is generally from about 0.5 to about 3 mm and, more specifically, from about 0.5 to about 2 mm, or from about 0.5 to about 1.5 mm. The first elongated groove 30 has a smoothly contoured inner edge 30a. The first elongated groove 30 has a generally rectangular shape. The first elongated groove 30 extends from a first end 20 to an opposing second end 22 as shown in FIG. 2 with a storage device 10a. A length L1 of the first elongated groove 30 is shown in FIG. 2. The length L1 is typically from about 100 to about 150 mm, and more specifically from about 115 to about 135 mm, or from about 120 to about 130 mm. The storage device 10a is the same as described above with respect to the storage device 10 of FIGS. 1A, 1B.

The second elongated groove 32 has a width W2 and a height H2. The width W2 is generally from about 1 to about 4 mm and, more specifically, from about 1 to about 3 mm, or from about 1 to about 2 mm. The height H2 is generally from about 0.5 to about 3 mm and, more specifically, from about 0.5 to about 2 mm, or from about 0.5 to about 1.5 mm. The second elongated groove 32 has a sharp edge 32a. The second elongated groove 32 has a generally rectangular shape. The second elongated groove 32 extends from the first end 20 to the opposing second end 22 as shown in FIG. 2 with a storage device 10b. A length L2 of the second elongated groove 32 is shown in FIG. 2. The length L2 is typically from about 100 to about 150 mm, and more specifically from about 115 to about 135 mm, or from about 120 to about 130 mm. The storage device 10b is the same as described above with respect to the storage device 10 of FIGS. 1A, 1B.

It is contemplated that the first and second elongated grooves may be identically shaped and sized. It is also contemplated that the first and second elongated groove may be sized and shaped differently than depicted in FIGS. 1A, 1B.

Referring to FIG. 2, the plurality of storage devices 10a, 10b is shown along with a chassis 100. As mentioned above, the storage devices 10a, 10b of FIG. 2 are the same as described above with respect to the storage device 10 of FIGS. 1A, 1B. It is noted that the orientation of storage device 10b has been rotated 180 degrees with respect to the storage devices 10, 10a.

The chassis 100 is configured to receive the storage devices 10a, 10b. The storage devices 10a, 10b are shown in the process of being received in the chassis 100 using arrow A, while the storage devices 10a, 10b are shown as being removed from the chassis 100 using arrow B. In one non-limiting example, the chassis 100 may be used in a computer system, such as a server. As discussed above, the chassis in other embodiments may be implemented in other computer systems such as network switches, stand-alone computers, or storage units (e.g., just a bunch of disks (JBOD)). The chassis 100 in one embodiment is configured to be stored on a rack of a computer system. The computer system typically includes shelving in the rack to store and securely retains chassis thereon.

The chassis 100 of FIG. 2 includes a front end 152 and a back end (not shown). The front end 152 of the chassis 100 forms a plurality of slots 106. Slots 106a-106e are specifically identified in FIG. 2.

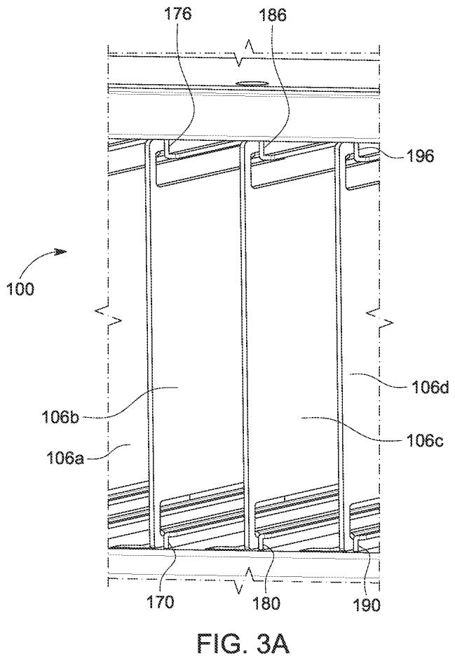

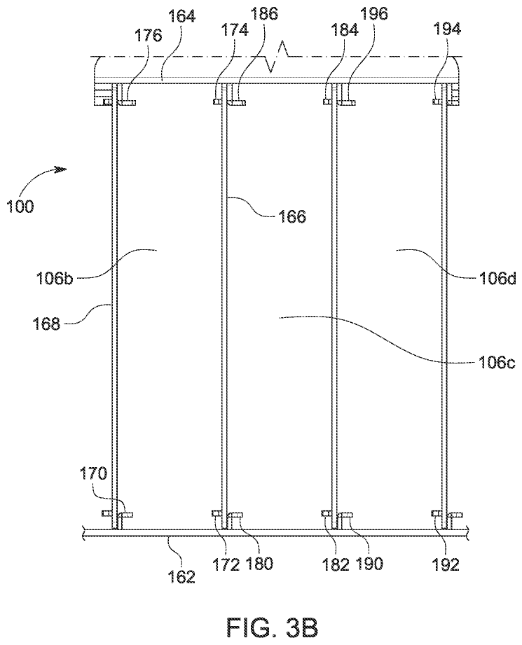

Referring to FIG. 3A, detailed and enlarged views of the slots 106a-106d are shown. Referring to FIG. 3B, detailed and enlarged views of the slots 106b-106d are shown. Each of the slots 106a-106d is configured to receive two storage devices 10 (e.g., storage devices 10a, 10b shown in FIG. 2). Referring to FIG. 3B, slot 106b is formed by a bottom wall 162, a top wall 164, a first side wall 166, and a second side wall 168. A plurality of guiding extensions 170, 172, 174, 176 is shown in which each of the plurality of guiding extensions 170, 172, 174, 176 extends inwardly into the slot 106b. The guiding extensions, in conjunction with the elongated grooves of the storage devices discussed above, assist in insertion, removal and securing of the storage devices in the slots of the chassis. The storage devices slide on the guiding extensions during the insertion and removal thereof into the chassis.

The guiding extension 170 extends from the bottom wall 162. The guiding extension 170 is in the shape of the letter “L.” As shown in FIG. 3B, the guiding extension 170 extends upwardly from the bottom wall 162 and then inwardly away from the second side wall 168. The guiding extensions 172, 174 extend from the first side wall 166. The guiding extension 172 is located adjacent to the bottom wall 162, while the guiding extension 174 is located adjacent to the top wall 164. The guiding extensions 172, 174 are generally rectangular shaped. The guiding extension 176 extends from the top wall 164. The guiding extension 176 is in the shape of the letter “L.” The guiding extension 176 extends downwardly from the top wall 164 and then inwardly away from the second side wall 168.

Guiding extensions 180, 182, 184, 186 are shown in slot 106c and guiding extensions 190, 192, 194, 196 are shown in slot 106d. These are similar to the above described guiding extensions 170, 172, 174, 176.

It is contemplated that the guiding extensions may all extend from side walls in another embodiment of a chassis. It is contemplated that the guiding extensions may all extend from the end walls in another embodiment of a chassis. It is contemplated that the guiding extensions may extend from a combination of side walls and ends walls in a further embodiment of a chassis. It is also contemplated that the positioning of the guiding extensions may differ from that shown in FIG. 3B.

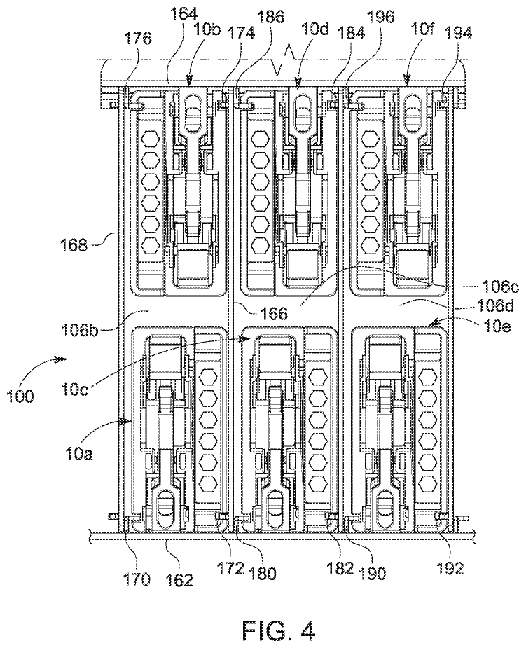

Referring to FIG. 4, a front perspective view of a plurality of storage devices 10a-10f in a plurality of slots 106b-106d of the chassis 100 is depicted. The plurality of slots 106b-106d is shown securing a plurality of storage devices 10a-10f. Specifically, slots 106b secures storage devices 10a, 10b. More specifically, the guiding extensions 170, 172 extend inwardly from opposing sides to securely engage the storage device 10a, while the guiding extensions 174, 176 extend inwardly from opposing sides to securely engage the storage device 10b. Similarly, guiding extensions 180, 182 secure storage device 10c, while guiding extensions 184, 186 secure storage device 10d. Similarly, guiding extensions 190, 192 secure storage device 10e, while guiding extensions 194, 196 secure storage device 10f.

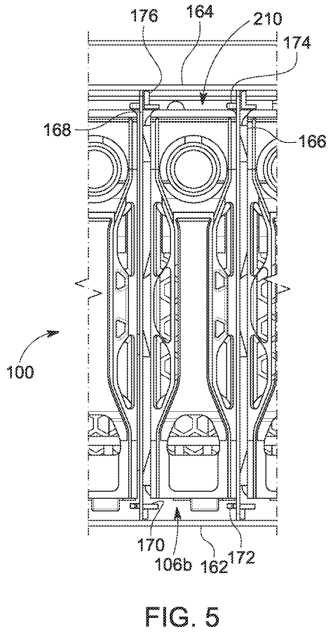

Referring to FIG. 5, an enlarged front view of the chassis 100 is partially shown. Unlike in FIG. 4 with storage devices 10a-10f, the chassis 100 of FIG. 5 includes a storage device 210 secured therein. The storage device 210 substantially occupies the space of the slot 106b formed by the bottom wall 162, the top wall 164, the first side wall 166, and the second side wall 168. In one embodiment, the storage device 210 is a 1×2.5″ hard disk drive (HDD). An HDD is an electro-magnetic data storage device that stores and retrieves digital data using magnetic storage and one or more rapidly rotating platters coated with magnetic material.

Thus, the slot 106b is configured to receive either a plurality of storage devices 10a, 10b (FIG. 4) or one storage device 210 (FIG. 5). This is advantageous in that the chassis 100 has flexibility in its configuration to hold multiple types and sizes of storage devices. The installation of different storage devices into the chassis is also efficient in both installation and replacement of the storage devices. Thus, the chassis may include a combination of first storage devices (10, 10a, 10b) and second storage devices 210.

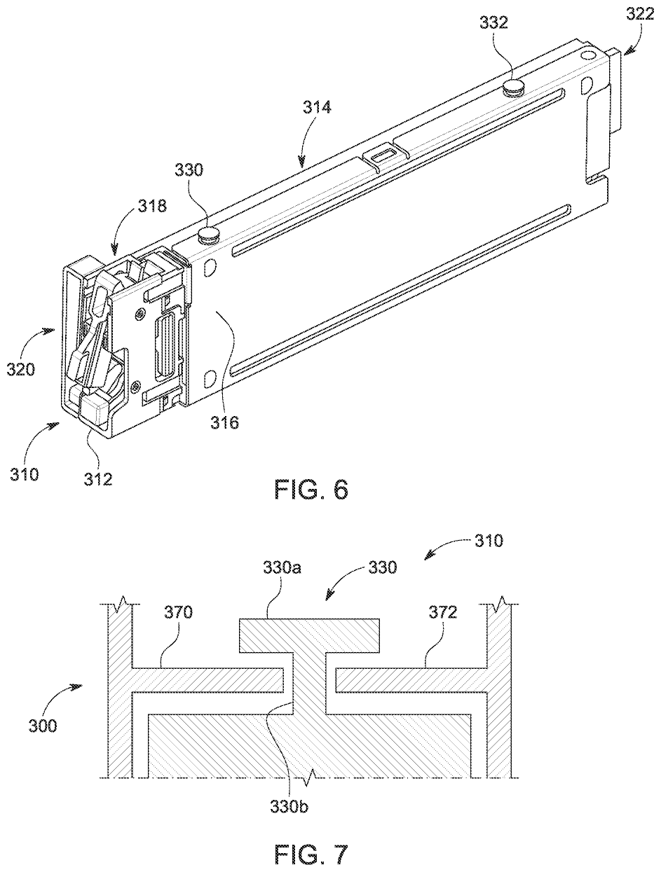

Referring to FIG. 6, a side perspective view of a storage device 310 is shown. The storage device 310 is an E1.S carrier according to another embodiment. The storage device 310 is the same as described above with respect to the storage devices 10, 10a, 10b, except with the features for engaging and securing with the guiding extensions of the chassis. Instead of the elongated grooves 30, 32 in the storage devices 10, 10a, 10b, the storage device 310 includes a plurality of securing protuberances 330, 332 that work in conjunction with the guiding extensions of the chassis to secure the storage device.

The storage device 310 includes a bottom surface 312, a top surface 314, a first side 316, an opposing second side 318, a first end 320, and an opposing second end 322. The top surface includes the plurality of securing protuberances 330, 332 configured to secure the storage device 310 with the chassis via the plurality of guiding extensions.

Referring to FIG. 7, an enlarged cross-sectional view of the securing protuberance 330 is shown when the storage device 310 is securely engaged to a plurality of opposing guiding extensions 370, 372 of a chassis 300. The securing protuberance 330 includes a top section 330a and a stem portion 330b. The securing protuberance 330 in this embodiment has a cross-sectional shape in form of a letter “T”. The top section 330a prevents or inhibits the storage device 310 from being repositioned inadvertently without removing the storage device 310 in a manner described above in FIG. 2 with respect to the storage devices 10a, 10b.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A chassis including at least one slot and a plurality of guiding extensions, the at least one slot configured for receiving a plurality of E1.S carriers or a 1×2.5 inch hard drive disk (HDD), the at least one slot formed by a top wall, a bottom wall, a first side wall, and a second side wall, the plurality of guiding extensions extending into the at least one slot, the plurality of guiding extensions including a first set of guiding extensions and a second set of guiding extensions, the first set of guiding extensions configured to receive and secure one of the plurality of E1.S carriers, the second set of guiding extensions configured to receive and secure a second one of the plurality of E1.S carriers.

2. The chassis of claim 1, wherein the at least one slot of the chassis is a plurality of slots.

3. The chassis of claim 1, wherein the first set of guiding extensions is located at or adjacent to the top wall, and the second set of guiding extensions is located at or adjacent to the bottom wall.

4. The chassis of claim 1, wherein at least one of the plurality of guiding extensions is “L” shaped.

5. The chassis of claim 1, wherein at least one of the plurality of guiding extensions is generally rectangular shaped.

6. The chassis of claim 1 further including the plurality of E1.S carriers secured in one of the at least one slot, each of the plurality of E1.S carriers including a bottom surface, a top surface, a first side, an opposing second side, a first end and an opposing second end, the first side forming a first elongated groove extending inwardly therefrom, the opposing second side forming a second elongated groove extending inwardly therefrom.

7. The chassis of claim 6, wherein the first and second elongated grooves are located adjacent to the bottom wall of each of the plurality of E1.S carriers.

8. The chassis of claim 6, wherein the at least one slot of the chassis is a plurality of slots, each of the plurality of slots including two of the plurality of E1.S carriers.

9. The chassis of claim 1 further including the plurality of E1.S carriers secured in one of the at least one slot, each of the plurality of E1.S carriers including a first end, an opposing second end, a first side, an opposing second side, a top surface, and a bottom surface, the top or the bottom surface including a securing protuberance configured to secure one of the plurality of E.1.S carriers with the chassis via the plurality of guiding extensions.

10. The chassis of claim 9, wherein the securing protuberance has a cross-sectional shape being in the form of a letter “T”.

11. A chassis including at least one slot and a plurality of guiding extensions, the at least one slot configured for receiving a plurality of first storage devices or a second storage device, the at least one slot being formed by a first end wall, a second end wall, a first side wall, and a second side wall, the plurality of guiding extensions extending into the at least one slot, the plurality of guiding extensions including a first set of guiding extensions and a second set of guiding extensions, the first set of guiding extensions configured to receive and secure one of the plurality of first storage devices, the second set of guiding extensions being configured to receive and secure a second one of the plurality of first storage devices.

12. The chassis of claim 11, wherein the at least one slot of the chassis is a plurality of slots.

13. The chassis of claim 11, wherein the first set of guiding extensions is located at or adjacent to the top wall, and the second set of guiding extensions is located at or adjacent to the bottom wall.

14. The chassis of claim 11, wherein at least one of the plurality of guiding extensions is “L” shaped.

15. The chassis of claim 11, wherein at least one of the plurality of guiding extensions is generally rectangular shaped.

16. A computer system comprising:
a chassis including at least one slot and a plurality of guiding extensions, the at least one slot configured for receiving a plurality of first storage devices or a second storage device, the at least one slot being formed by a first end wall, a second end wall, a first side wall, and a second side wall, the plurality of guiding extensions extending into the at least one slot, the plurality of guiding extensions including a first set of guiding extensions and a second set of guiding extensions, the first set of guiding extensions configured to receive and secure one of the plurality of first storage devices, the second set of guiding extensions being configured to receive and secure a second one of the plurality of first storage devices.

17. The computer system of claim 16, wherein the first storage devices are a plurality of E1.S carriers, and the second storage device is a 1×2.5 inch hard drive disk (HDD).

18. The computer system of claim 16, wherein the computer system is a server.

19. The computer system of claim 16, wherein the at least one slot of the chassis is a plurality of slots.

20. The computer system of claim 16, wherein the first set of guiding extensions is located at or adjacent to the top wall, and the second set of guiding extensions is located at or adjacent to the bottom wall.
